(19) United States
(12) Patent Application Publication
(10) Pub. No.: US 2012/0062480 A1
(43) Pub. Date: Mar. 15, 2012

(54) CAPACITIVE TOUCH SENSOR AND METHOD FOR MANUFACTURING THE SAME

(75) Inventors: Jao-Ching Lin, Taipei City (TW); Abel Lin Chu, Taipei City (TW); Yao-Chung Kuo, Taipei City (TW)

(73) Assignee: SENTELIC CORPORATION, Taipei City (TW)

(21) Appl. No.: 12/967,324

(22) Filed: Dec. 14, 2010

(30) Foreign Application Priority Data
Sep. 14, 2010 (TW) 099131026

(51) Int. Cl. G06F 3/041; H05K 3/10

(52) U.S. Cl. 345/173; 29/846

(57) ABSTRACT

The present invention provides a capacitive touch sensor and a method for manufacturing the same. The capacitive touch sensor includes at least one transparent insulation substrate and at least one transparent capacitive touch conductor. The capacitive touch conductor is coated on the insulation substrate and formed with a boundary. The capacitive touch conductors are electrically connected to each other to form at least one first and second electrical-conductive set. At least one recess region is defined in the boundary. The recess region increases the light transmittance of the insulation substrate, reduces the necessary brightness of a light source for the capacitive touch pad, and saves the material cost.

This application claims the priority benefit of Taiwan patent application number 099131026 filed on Sep. 14, 2010.

### BACKGROUND OF THE INVENTION

1. Field of the Invention

The present invention relates to a touch sensor and a method for manufacturing the same, and in particular to a capacitive touch panel or a touch screen which can reduce the necessary brightness of a light source and the materials by using the recess region to increase the light transmittance.

2. Description of Prior Art

With the rapid advancement of information technology and communication network, electronic products have been widely used in our daily life. Thus, touch sensors are developed in order to enhance the functions of the electronic products. Existing touch sensors are primarily divided into four categories, including the resistance-type, the capacitance-type, the acoustic-type and the optical-type based on their principles of sensing signals. The capacitance-type touch sensor (referred to “capacitive touch sensor” hereinafter) becomes more and more popular and is widely adopted in various electronic products, such as mobile phone, panel computer, walkman displayer, monitor and etc as it is dust-proof, fire-resistant and has the high-definition. The capacitive touch sensor is configured to identify the position of a contact based on a change of capacitance. More specifically, the capacitive touch sensor is configured to identity the coordinates of a contact point based on a change of capacitance between electrodes caused by the approach of an object (such as a finger or other conductor). Accordingly, a touch control effect can be achieved.

Capacitive touch conductors are provided in the capacitive touch sensors to detect a minor capacitance between a finger and the conductors. The capacitive touch conductors are formed into a solid rhombus pattern. The rhombus pattern is a symmetrical pattern constituted of rhombus, hexagon or octagon. With this configuration, the distance between neighboring lines is shortened to enhance the capacitance effect.

The capacitive touch conductors are electrically connected to each other, thereby forming at least one column of conductors and at least one row of conductors separately. The column of conductors and the row of conductors are staggered without any electrical connection. The column of conductors and the row of conductors are electrically connected to a control chip. When the user touches the column of conductors or the row of conductors, the touched column of conductors and the row of conductors send a signal to the control chip for achieving a desired touch control function.

Generally speaking, a transparent touch sensor, also known as a transparent touch pad or a touch panel/screen, can be provided with a liquid crystal display (referred to as “LCD” hereinafter) on one side. The light emitted by the LCD enters the transparent capacitive touch pad and exits there from. The light transmittance of the capacitive touch conductors is smaller than that of a glass substrate or reinforced plastic materials forming the transparent capacitive touch pad, so that the shape and size of the capacitive touch conductors may affect the light transmittance of the capacitive touch pad. In practice, the capacitive touch conductors of a solid rhombus pattern may negatively affect a light source of the LCD and reduce the light transmittance. As a result, the necessary brightness of the light source for the capacitive touch pad has to be increased, and more materials have to be used to configure the solid rhombus pattern.

According to the above, the prior art has disadvantages as follows:

(1) the light transmittance is low;

(2) the necessary brightness of the light source for the capacitive touch pad is increased; and

(3) the material cost is high.

Therefore, it is an important issue for the present inventor and the manufacturers in this field to solve the above-mentioned problems in prior art.

### SUMMARY OF THE INVENTION

In order to solve the above problems, an objective of the present invention is to provide a capacitive touch sensor and a method for manufacturing the same, whereby the light transmittance thereof is increased.

Another objective of the present invention is to provide a capacitive touch sensor and a method for manufacturing the same, whereby the necessary brightness of a light source for the capacitive touch sensor is reduced.

A further objective of the present invention is to provide a capacitive touch sensor and a method for manufacturing the same, whereby the material cost is reduced.

In order to achieve the above objective, the present invention is to provide a capacitive touch sensor, including at least one insulation substrate and at least one capacitive touch conductor. The capacitive touch conductor is coated on the insulation substrate. One side of the insulation substrate is provided with at least one LCD light-emitting element. Each of the capacitive touch conductors is formed with a boundary in which a recess region is defined. The recess region has a bottom. The capacitive touch conductors are electrically connected to each other to form at least one first electrical-conductive set and at least one second electrical-conductive set separately. The first electrical-conductive set and the second electrical-conductive set are staggered without any electrical connection. The first electrical-conductive set and the second electrical-conductive set are electrically connected to a control unit respectively. Thus, a light source generated by the LCD light-emitting element on one side of the insulation substrate pierces through the insulation substrate and the capacitive touch conductors coated on the insulation substrate. Since the capacitive touch conductors are formed with the recess regions, the light transmittance of the transparent capacitive touch sensor is increased, the necessary brightness of the light source generated by the LCD light-emitting element is reduced, and the material cost for the capacitive touch conductors is reduced.

The present invention further provides a method for manufacturing a capacitive touch sensor, including steps of: coating a plurality of capacitive touch conductors on an insulation substrate; forming a boundary on the periphery of each capacitive touch conductor; electrically connecting the plurality of capacitive touch conductors to each other to form a plurality of first electrical-conductive sets and a plurality of second electrical-conductive sets separately, wherein the plurality of first electrical-conductive sets and the plurality of second electrical-conductive sets are staggered without any electrical connection; forming at least one recess region in the boundary of each capacitive touch conductor; and forming the recess region on the insulation substrate. By this structure, a light source generated by the LCD light-emitting element on one side of the insulation substrate can pierce through the insulation substrate and the capacitive touch conductors coated on the insulation substrate. Since the capacitive touch conductors are formed with the recess regions, the light transmittance of the transparent capacitive touch sensor is increased, the necessary brightness of the light source generated by the LCD light-emitting element is reduced, and the material cost for the capacitive touch conductors is reduced.

### BRIEF DESCRIPTION OF THE DRAWINGS

FIG. 1 is a front view showing a first preferred embodiment of the present invention;

FIG. 2A is a cross-sectional view (I) showing the first preferred embodiment of the present invention;

FIG. 2B is a cross-sectional view (II) showing the first preferred embodiment of the present invention;

FIG. 2C is a partial perspective view showing the preferred embodiment of the present invention;

FIG. 3 is a front view showing a second preferred embodiment of the present invention;

FIG. 4A is a cross-sectional view (I) showing the second preferred embodiment of the present invention;

FIG. 4B is a cross-sectional view (II) showing the second preferred embodiment of the present invention;

FIG. 4C is a partial perspective view showing the preferred embodiment of the present invention;

FIG. 5 is a flow chart showing the method of the present invention;

FIG. 6 is a schematic view (I) showing a third preferred embodiment of the present invention;

FIG. 7 is a schematic view (II) showing the third preferred embodiment of the present invention; and

FIG. 8 is a schematic view (III) showing the third preferred embodiment of the present invention.

### DETAILED DESCRIPTION OF THE INVENTION

The above objectives and structural and functional features of the present invention will be described in more detail with reference to preferred embodiments thereof shown in the accompanying drawings

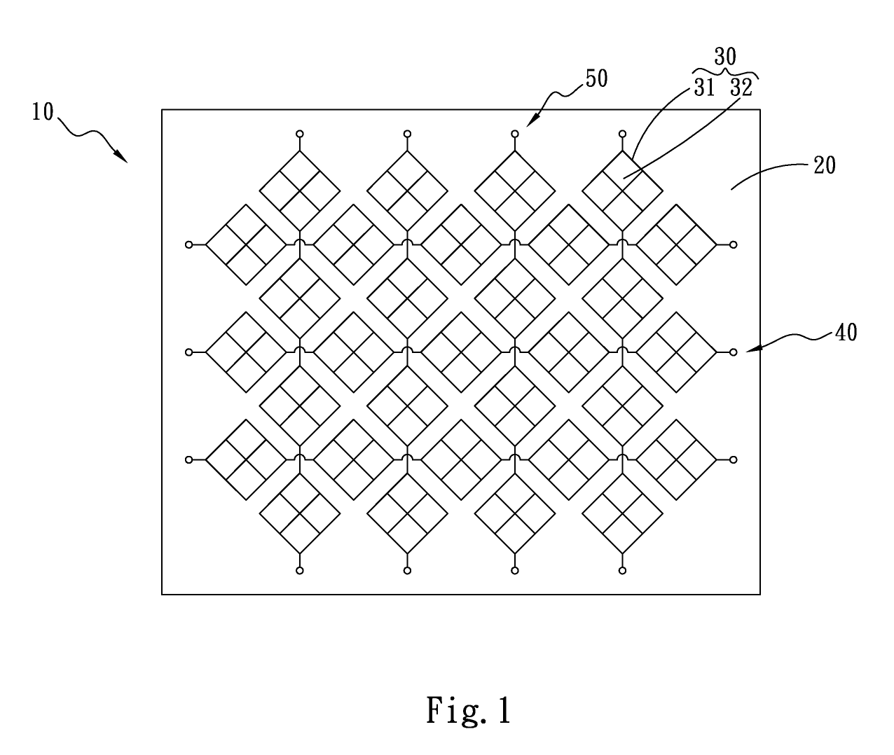

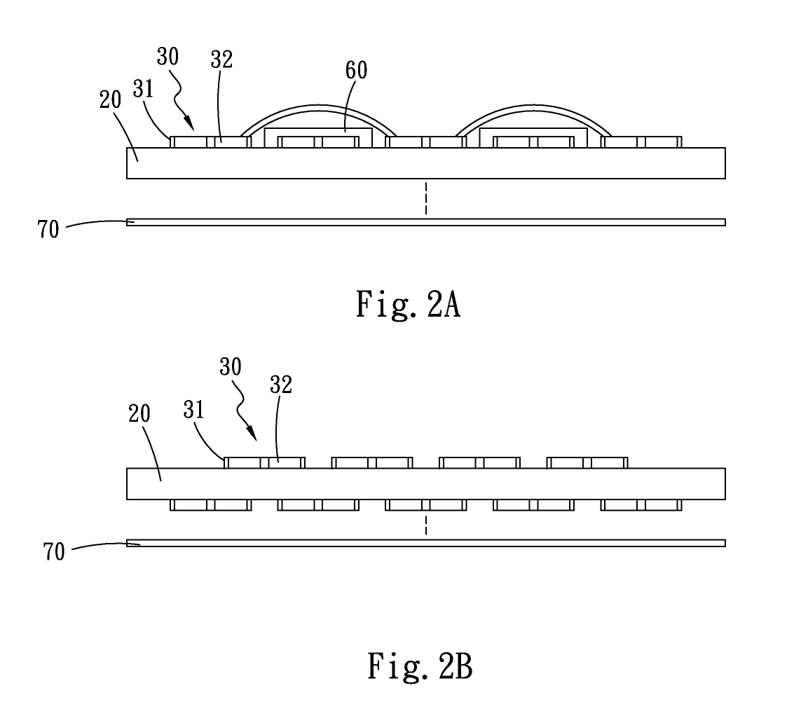

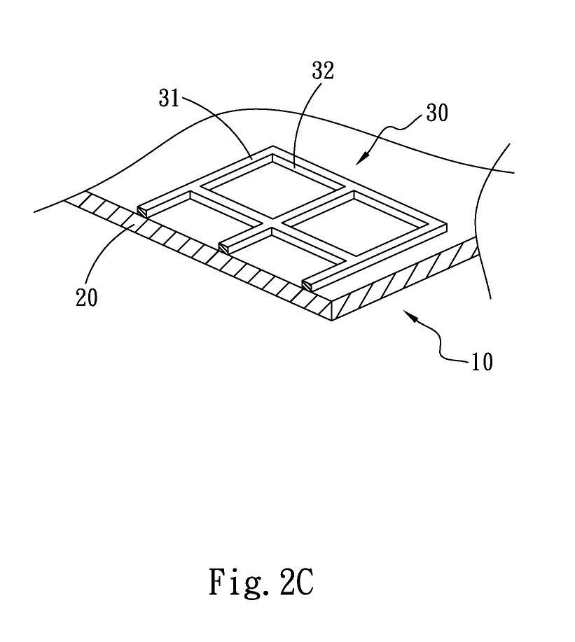

Please refer to FIGS. 1, 2A, 2B and 2C, which show the first embodiment of the present invention. The present invention provides a capacitive touch sensor 10, which includes at least one insulation substrate 20 and at least one capacitive touch conductor 30. The insulation substrate 20 is transparent. The capacitive touch conductor 30 is a transparent conductor to be coated on the insulation substrate 20. The capacitive touch conductors 30 are electrically connected to each other to form at least one first electrical-conductive set 40 and at least one second electrical-conductive set 50 separately.

The first electrical-conductive set 40 and the second electrical-conductive set 50 are staggered without any electrical connection. In the first embodiment, the first electrical-conductive set 40 and the second electrical-conductive set 50 are provided on one side of the insulation substrate 20 to be electrically connected to one control unit respectively.

The first electrical-conductive set 40 and the second electrical-conductive set 50 are simultaneously coated on one side of the insulation substrate 20. The staggered portions between the first electrical-conductive set 40 and the second electrical-conductive set 50 are separated by an insulation material 60 (as shown in FIG. 2A). Alternatively, the first electrical-conductive set 40 and the second electrical-conductive set 50 are coated on different sides of the insulation substrate 20 respectively. The first electrical-conductive set 40 and the second electrical-conductive set 50 are staggered and separated from each other by the insulation substrate 20 (as shown in FIG. 2B).

A boundary 31 is formed on the periphery of each capacitive touch conductor 30 of the first electrical-conductive set 40 and the second electrical-conductive set 50. At least one recess region 32 is defined in the boundary 31. The recess region 32 penetrates through the capacitive touch conductor 30 and is formed on the insulation substrate 20. Therefore, when the capacitive touch sensor 10 is in use, at least one light-emitting element 70 (such as a LCD) provided on one side of the insulation substrate 20 generates a light source to emit light to the insulation substrate 20. The light pierces through the transparent insulation substrate 20 and the capacitive touch conductors 30. Since the capacitive touch conductors 30 have the recess regions 32, the light emitted by the light-emitting element 70 can directly pierce the insulation substrate 20, thereby increasing the light transmittance of the capacitive touch sensor 10 and reducing the necessary brightness of the light source for the capacitive touch sensor 10.

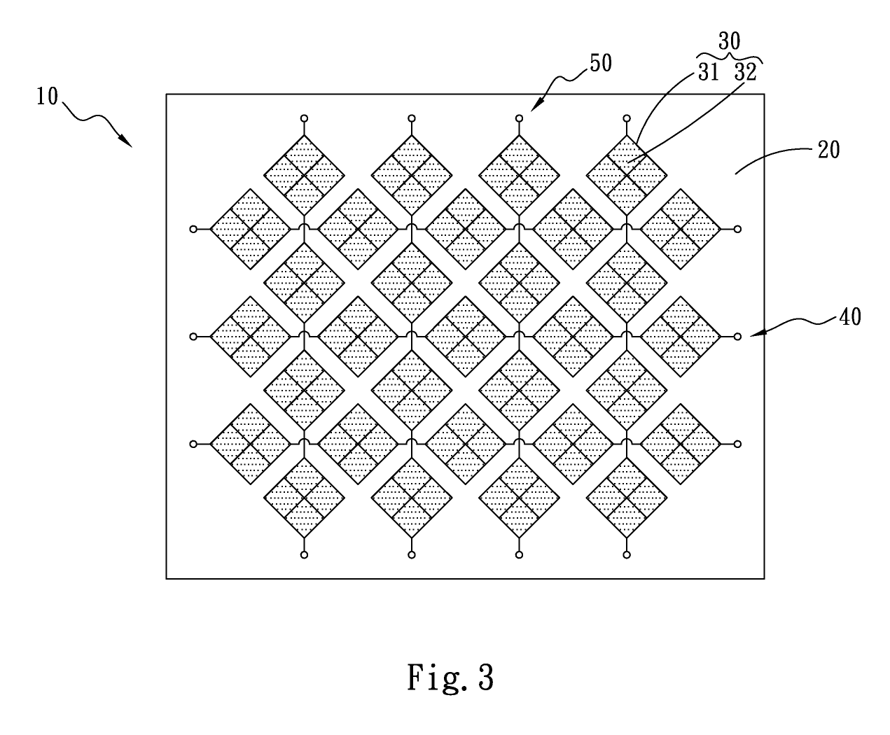

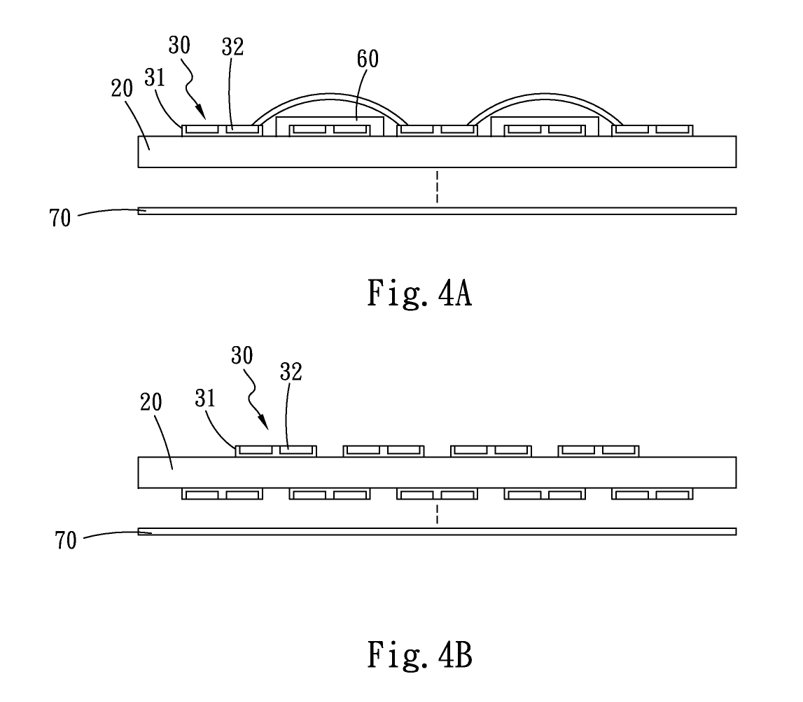

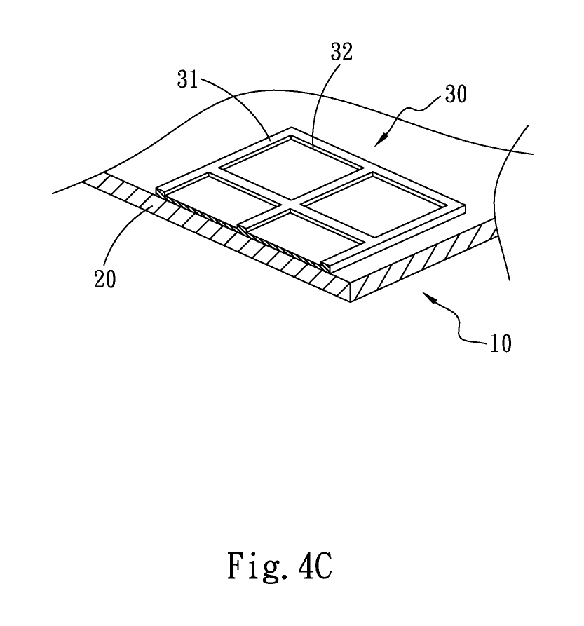

Please refer to FIGS. 3, 4A, 4B and 4C, which show the second embodiment of the present invention. The second embodiment is substantially the same as the previous embodiment in terms of the connection of elements and their operations, and thus the redundant description is omitted. The difference between the second embodiment and the first embodiment lies in that: the recess portion 32 of the second embodiment does not penetrate through the capacitive touch conductor 30 and is formed on the capacitive touch conductors 30. Thus, the light generated by the light-emitting element 70 can also directly pierce the insulation substrate 20, thereby increasing the light transmittance of the capacitive touch sensor 10 and reducing the necessary brightness of the light source for the capacitive touch sensor 10.

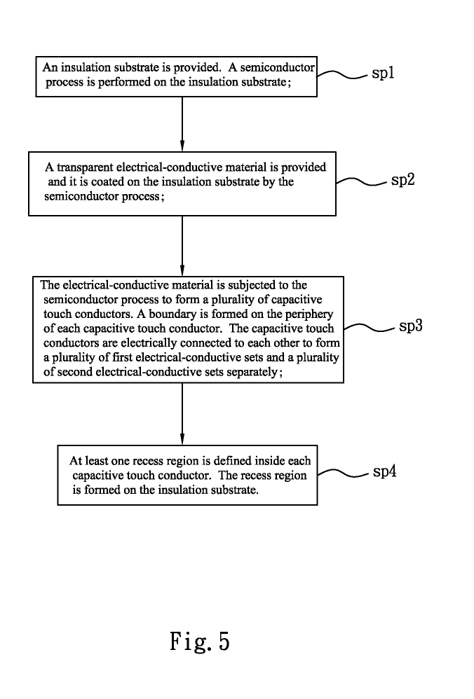

Please refer to FIG. 5 together with the previous figures. FIG. 5 is a flow chart showing the steps of the method for manufacturing the capacitive touch sensor of the present invention. The method includes the following steps.

In a step 1 (sp1), an insulation substrate is provided. A semiconductor process is performed on the insulation substrate.

In a step 2 (sp2), a transparent electrical-conductive material is provided. The electrical-conductive material is coated on the insulation substrate by the semiconductor process.

In a step 3 (sp3), the electrical-conductive material is subjected to the semiconductor process to form a plurality of capacitive touch conductors. A boundary is formed on the periphery of each capacitive touch conductor. The capacitive touch conductors are electrically connected to each other to form a plurality of first electrical-conductive sets and a plurality of second electrical-conductive sets separately.

In a step 4 (sp4), at least one recess region is defined inside each capacitive touch conductor. The recess region is formed on the insulation substrate.

The semiconductor process mentioned above may be an etching process or a superposing process. In the etching process, a transparent electrical-conductive material such as an Indium tin oxide (ITO) film is coated on the transparent insulation substrate 20. Etching paste is applied to the portions of the ITO film which are to be removed. After cleaning the etching paste, the capacitive touch conductors 30 as well as the boundary 31 and the recess region 32 of the capacitive touch conductors 30 are formed. The recess portion 32 may or may not penetrate through the capacitive touch conductor 30, and it is formed on the capacitive touch conductor 30 or the insulation substrate 20.

Alternatively, in the etching process, a transparent electrical-conductive material such as an Indium tin oxide (ITO) film is coated on the transparent insulation substrate 20. A photo-resist material is applied to the portions of the ITO film which are to be kept. After the portions which the photo-resist material is not applied are etched away by acids, the capacitive touch conductors 30 as well as the boundary 31 and the recess region 32 of the capacitive touch conductors 30 are formed. The recess portion 32 may or may not penetrate through the capacitive touch conductor 30, and it is formed on the capacitive touch conductor 30 or the insulation substrate 20.

In the superposing process, a photo-resist material is applied to the positions of the transparent insulation substrate 20 which are to be removed. After the portions applied with the photo-resist material are washed away by a weak-base cleaning agent, the capacitive touch conductors 30 as well as the boundary 31 and the recess region 32 of the capacitive touch conductors 30 are formed. The recess portion 32 may or may not penetrate through the capacitive touch conductor 30, and it is formed on the capacitive touch conductor 30 or the insulation substrate 20. The bottom 321 may be formed on the position corresponding to the capacitive touch conductor 30 or the insulation substrate 20.

The capacitive touch pad 10 is further provided with a control unit (not shown). The control unit is electrically connected to the first electrical-conductive set 40 and the second electrical-conductive set 50. When the user touches the first electrical-conductive set 40 and the second electrical-conductive set 50, the first electrical-conductive set 40 and the second electrical-conductive set 50 send a signal to the control unit, thereby achieving the touch control effect.

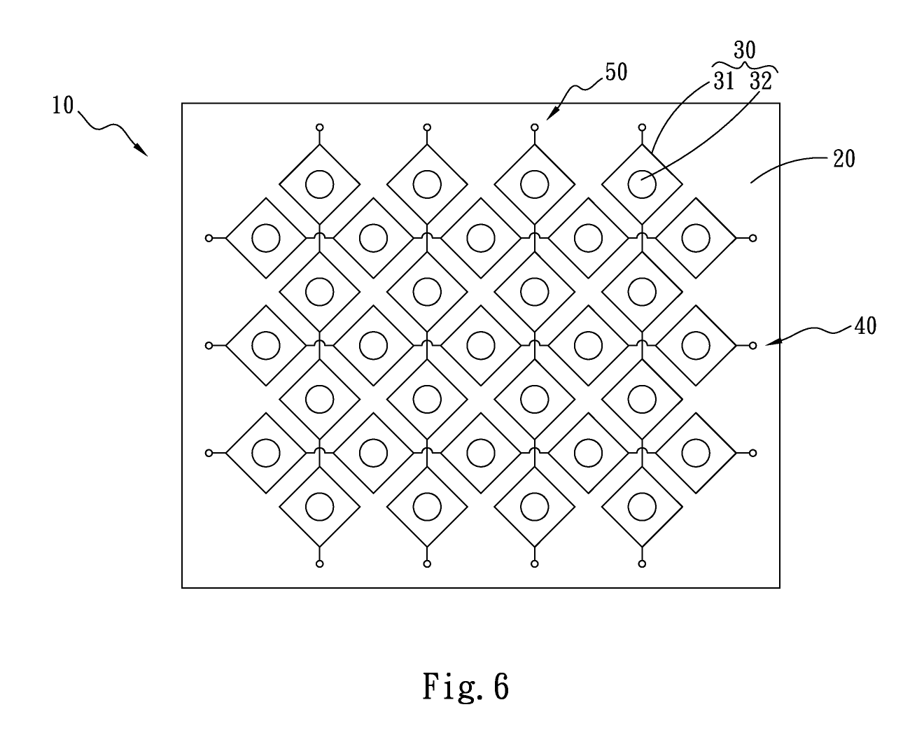

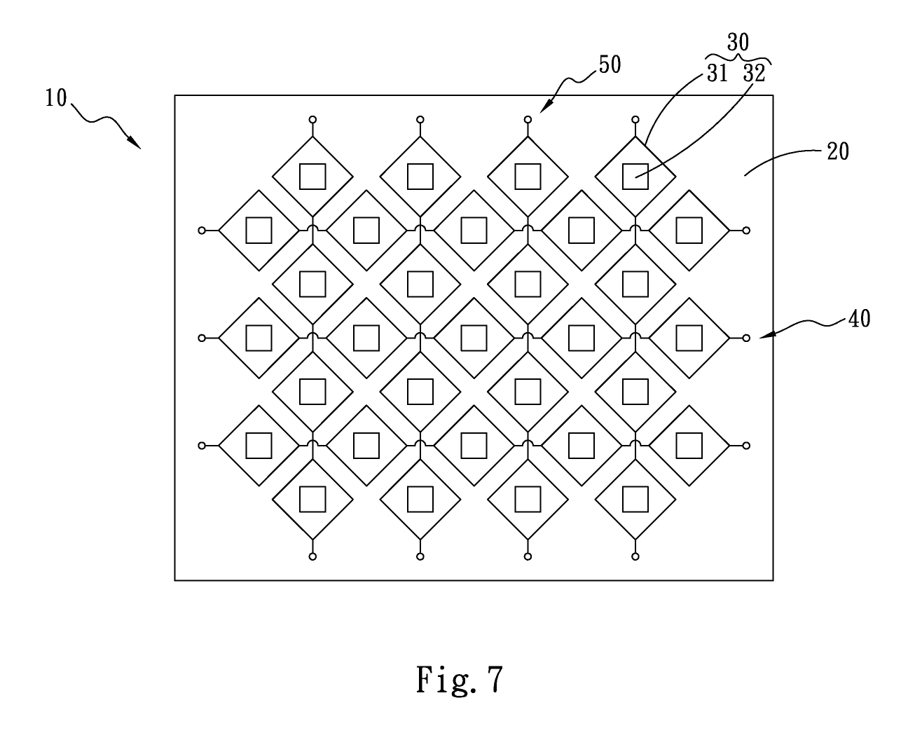

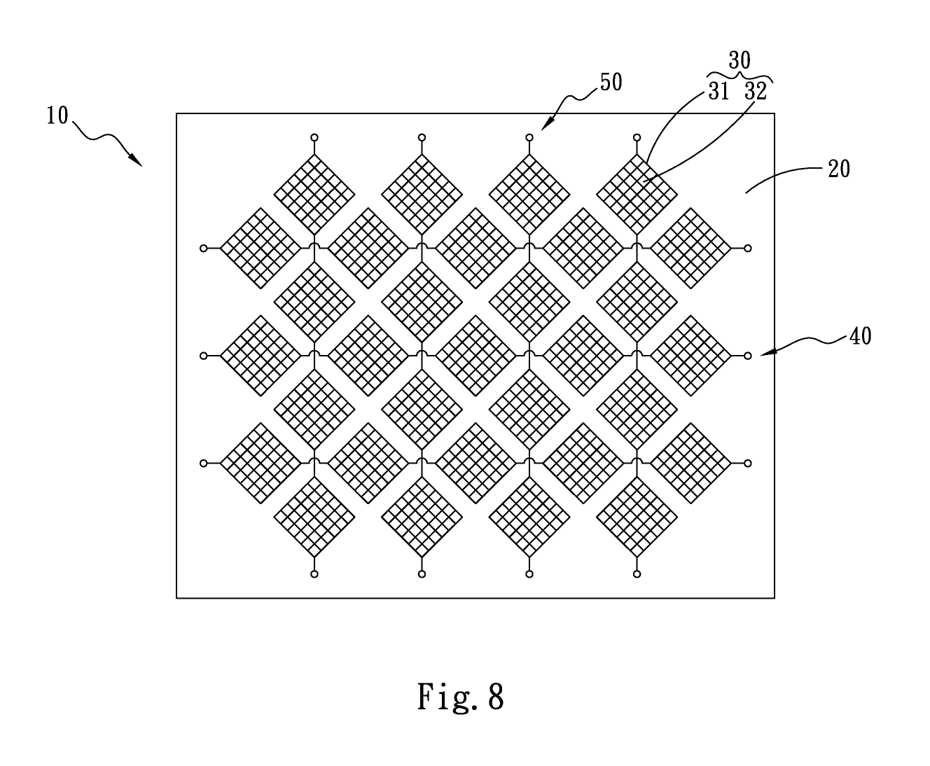

Please refer to FIGS. 6, 7 and 8, which show the third embodiment of the present invention. The periphery of each capacitive touch conductor 30 is formed with the boundary 31 as shown in FIG. 2A, 2B or 4A, 4B. The capacitive touch conductor 30 may be formed into other symmetrical shapes such as a regular hexagon or regular octagon. At least one recess region 32 is defined in the boundary 31, and the recess region 32 is formed on the insulation substrate 20. The recess region 32 may be formed into other suitable shape like a ring, a chessboard, a honeycomb or a mesh on demands. The above-mentioned shapes can also increase the light transmittance of the capacitive touch pad 10 and reduce the necessary brightness of the light source for the capacitive touch sensor 10.

In comparison with prior art, the capacitive touch sensor and the method for manufacturing the same have the following advantages:
(1) the light transmittance of the capacitive touch sensor is increased by the recess regions;
(2) the necessary brightness of the light source for the capacitive touch pad is reduced; and
(3) the material cost is saved.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A capacitive touch sensor, including:
at least one insulation substrate; and
at least one capacitive touch conductor coated on the insulation substrate, each capacitive touch conductor being formed with a boundary in which at least one recess region is defined.

2. The capacitive touch sensor according to claim 1, wherein the insulation substrate is transparent.

3. The capacitive touch sensor according to claim 1, wherein the capacitive touch conductor is transparent.

4. The capacitive touch sensor according to claim 1, wherein the recess region does not penetrate through the capacitive touch conductor.

5. The capacitive touch sensor according to claim 1, wherein the recess region penetrates through the capacitive touch conductor.

6. The capacitive touch sensor according to claim 1, wherein the capacitive touch conductors are electrically connected to each other to form at least one first electrical-conductive set and at least one second electrical-conductive set separately, and wherein the first electrical-conductive set and the second electrical-conductive set are staggered without any electrical connection.

7. The capacitive touch sensor according to claim 6, wherein the first electrical-conductive set and the second electrical-conductive set are coated on different sides of the insulation substrate, and wherein the first electrical-conductive set and the second electrical-conductive set are staggered and separated from each other by the insulation substrate.

8. The capacitive touch sensor according to claim 6, further including a control unit electrically connected to the first electrical-conductive set and the second electrical-conductive set.

9. The capacitive touch sensor according to claim 6, wherein the first electrical-conductive set and the second electrical-conductive set are simultaneously coated on one side of the insulation substrate, and the staggered portions between the first electrical-conductive set and the second electrical-conductive set are separated by an insulation material.

10. A method for manufacturing a capacitive touch sensor, including steps of:
providing a transparent insulation substrate, performing a semiconductor processing on the insulation substrate;
providing a transparent electrical-conductive material, coating the electrical-conductive material on the insulation substrate by the semiconductor processing;
forming a plurality of capacitive touch conductors from the electrical-conductive material by the semiconductor processing, forming a boundary on a periphery of each of the capacitive touch conductors, and electrically connecting the capacitive touch conductors to form a plurality of first electrical-conductor sets and a plurality of second electrical-conductive sets separately; and
defining at least one recess region in the boundary of each capacitive touch conductor, and forming the recess region on the insulation substrate.

11. The method according to claim 10, further including a step of providing a control unit, the control unit being electrically connected to the first electrical-conductive set and the second electrical-conductive set.

12. The method according to claim 10, wherein the recess region does not penetrate through the capacitive touch conductor.

13. The method according to claim 10, wherein the recess region penetrates through the capacitive touch conductor.
